(19) United States
(12) Patent Application Publication
(10) Pub. No.: US 2025/0372276 A1
(43) Pub. Date: Dec. 4, 2025

(54) ELECTRON BEAM DEFLECTOR

(71) Applicant: AQUASIUM TECHNOLOGY LIMITED, Cambridge (GB)

(72) Inventor: Alex O'FARRELL, Cambridge (GB)

(21) Appl. No.: 18/707,837

(22) PCT Filed: Nov. 14, 2022
(86) PCT No.: PCT/GB2022/052882

§ 371 Date: May 6, 2024

(30) Foreign Application Priority Data
Nov. 25, 2021 (GB) 2117009.7

(51) Int. Cl. G21K 1/06; B23K 15/00; B23K 15/06

(52) U.S. Cl. CPC G21K 1/06; B23K 15/002; B23K 15/06; G21K 2201/068

(57) ABSTRACT

There is provided an electron beam deflector (32) for use in electron beam welding, the deflector (32) comprising a planar body (32) defining at least one channel (36) enabling passage of an electron beam (14) to a weld site, wherein at least one deflector element (44) in the form of an electromagnetic coil is disposed within the at least one channel (36) and the electromagnetic coil (44) is configured to modify the direction of travel of an electron beam so as to deflect the electron beam (14) to be incident substantially orthogonal to a weld site of a workpiece. The planar body (32) comprises a separate base portion (40) and lid portion (42).

### FIELD OF THE INVENTION

This invention relates to an electron beam deflector and in particular such a deflector for use in electron beam welding.

### BACKGROUND TO THE INVENTION

Electron beam welding is used for mass manufacturing in markets such as automotive and sensors where high precision and low heat input welds are required when producing thousands of parts per day. In such mass production environments, the rapid deflection speed of the electron beam is commonly the reason it is the chosen technology.

Commonly tooling or jigging is used to clamp components together so they do not move or warp whilst the heating energy of the electron beam is impinged upon them. Such tooling is often large to ensure good mechanical strength for clamping which then prevents the electron beam from having a direct path to the weld surface of the components. This is a particular issue when welding of electrical batteries for vehicles where many welds are required over a large area and the connections for the batteries must be well clamped together to ensure a high quality of weld is achieved. Solutions such as moving the part through an evacuated weld chamber using mechanical motion or moving an electron gun further from the part being processed have been trialled, but this complicates positional alignment of the parts and requires a much larger vacuum chamber which then greatly increases the cycle time of the process.

### SUMMARY OF THE INVENTION

In accordance with the invention, there is provided an electron beam deflector for use in electron beam welding, the deflector comprising a planar body defining at least one channel enabling passage of an electron beam through the planar body to reach a weld site, wherein at least one deflector element is disposed within the at least one channel and the at least one deflector element is configured to modify the direction of travel of an electron beam. Such a deflector is positionable within a vacuum chamber where welding is to take place and provides localised deflection of the electron beam outside a gun column generating the electron beam.

Preferably the deflector element is configured to deflect an electron beam to be incident substantially orthogonal to a weld site on a workpiece.

The electron beam deflector is preferably configured to be locatable within a vacuum chamber proximal a workpiece to be welded, typically locatable on top of a tooling jig securing a workpiece to be welded, and preferably includes vents to allow evacuation of any air within the planar body.

The deflector may further comprise a plurality of channels with at least one deflector element disposed within each channel.

The plurality of channels may be arranged as an array, typically as an offset array.

Each deflector element preferably has a magnetic field strength and orientation dependent on distance from an undeflected axis of the electron beam as generated by an electron gun.

The planar body may comprise a separate base portion and lid portion connectable together. This assists with locating deflector elements within the planar body and facilitates electrical connections between the deflector elements and electrical components.

Preferably each channel is formed within the base portion and grooves formed within the base portion connect to each channel. This allows electrical wires to be routed easily throughout the base portion and used to electrically connect deflector elements to each other and to an external power source.

The lid portion is preferably formed with apertures corresponding to locations of channels within the base portion.

A plurality of deflector elements may be disposed within the or each channel, each deflector element configured to modify a different aspect of an electron beam. Thus deflector elements to adjust direction, focus, and/or beam width may be provided.

Each deflector element preferably comprises an electromagnetic coil.

The invention will now be described by way of example and with reference to the accompanying drawings in which:

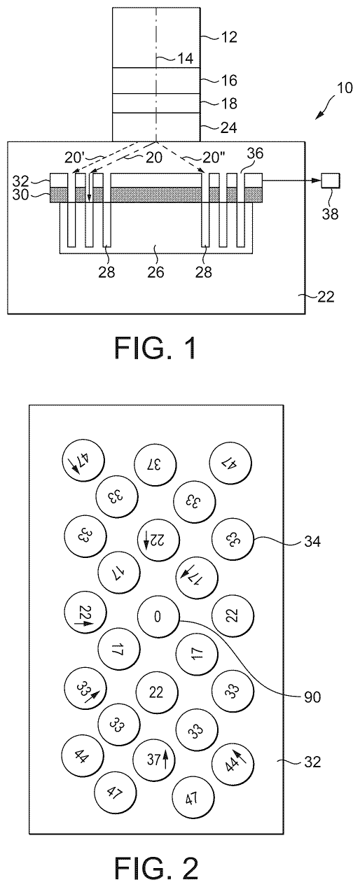

FIG. 1 is a schematic diagram of electron beam welding apparatus;

FIG. 2 is a plan view of a deflection plate;

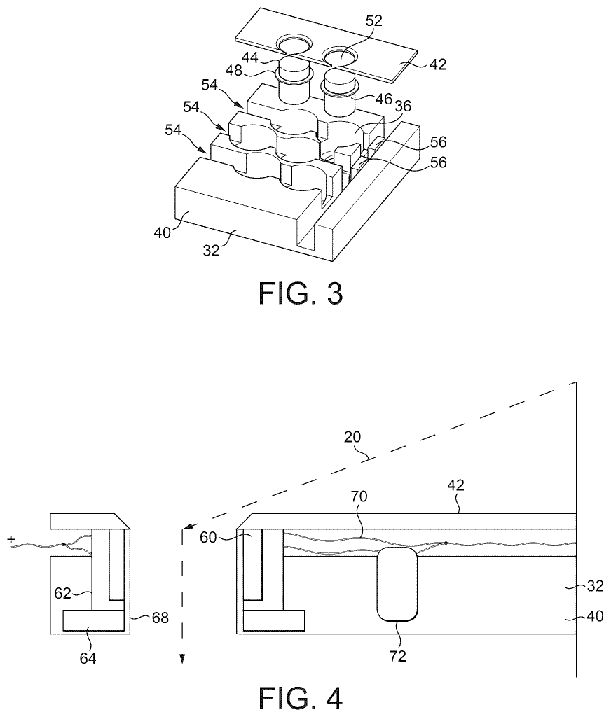

FIG. 3 is an exploded partial view of a first embodiment of the deflection plate;

FIG. 4 is a cross-section of part of a second embodiment of the deflection plate;

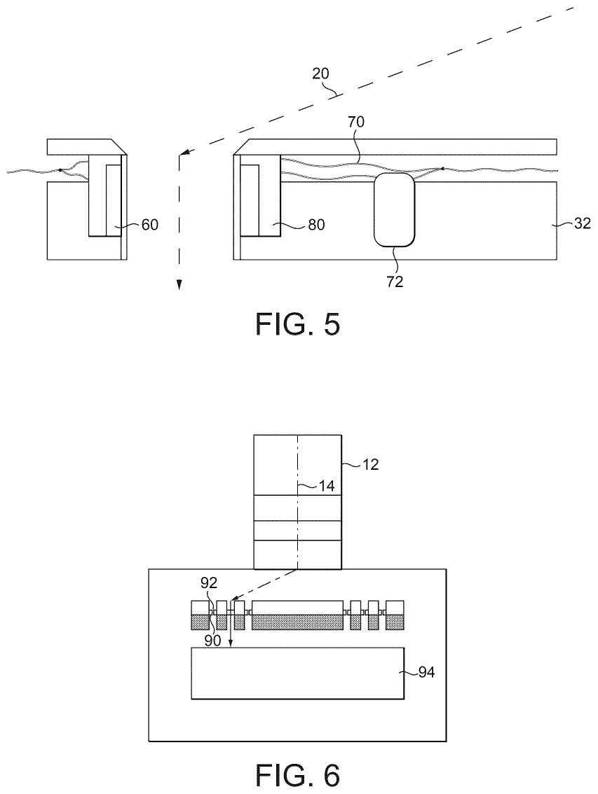

FIG. 5 is a cross-section of part of a third embodiment of the deflection plate;

FIG. 6 is a schematic diagram of a testing arrangement for the deflection plate; and

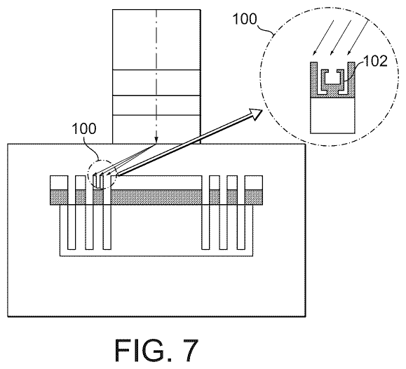

FIG. 7 is a schematic diagram of the deflection plate with beam analysis stations.

### DESCRIPTION

Electron beam welding apparatus 10 is shown schematically in FIG. 1 and comprises an electron beam gun 12 for emitting an electron beam 14 and focus element 16, fast focus element 18 and fast deflection element 24 located within gun 12 for modifying the properties of electron beam 14 and adjusting its position away from a central undeflected axis corresponding to the axial path through the centre of gun 12. Beam 14 has its position adjusted by elements 16, 18 and 24 to weld multiple positions, see deflected beams 20, 20′, 20″ by way of example. A workpiece 26 requiring welding is situated in chamber 22, this being by way of example a car battery requiring welded connections to a plurality of individual battery cells 28.

Battery 26 is secured firmly in position by tooling or clamping jig 30. A planar body in the form of deflection plate 32 is mounted on clamping jig 30 within chamber 22 so as to be positioned directly above workpiece battery 26. As can be seen in FIG. 2, plate 32 is formed with a plurality of circular apertures 34 which extend as channels 36 through plate 32 so as to allow electron beam 14 to impinge on weld sites associated with cells 28 and located beneath plate 32. Typically clamping jig 30 is formed with open linear channels to allow welding access to cells 28.

Within each channel 36 of plate 32 is located at least one electron beam deflector element such as cylindrical electromagnetic coil 44, see FIG. 3, to exert localised deflection on deflected beams 20, 20′, 20″ as they reach plate 32. An external power source 38 is connected to plate 32 to provide power to coils 44 so that they are able to generate a localised magnetic field.

In prior art welding without such a deflection plate, electron beam 14 hits all weld sites, apart from any weld site situated directly below the axis coinciding with undeflected beam 14, at a slight angle of inclination which impairs the quality of the weld. Deflection plate 32 provides localised correction of the direction of travel of the electron beam in chamber 22 proximal battery 26 and outside the structure of gun 12. Plate 32 modifies the direction of travel of electron beams 20, 20′, 20″ to ensure they are directed substantially orthogonal to weld sites at each battery cell 28 ensuring good quality welds. Where a workpiece is configured to have an irregular surface, the deflector element within plate 32 and proximal the weld site can adjust for this so that the electron beam travels along channel 36 slightly off axis to impinge substantially orthogonal to the irregular surface.

An exploded view of plate 32 is shown in FIG. 3, plate 32 comprising a base portion 40 and a lid portion 42 and typically having a thickness of around 10 to 30 mm. Base portion 40 is formed with a plurality of channels 36 in which electromagnetic coils 44 locate, with base 40 being covered by apertured lid portion 42 of which only a small amount is shown for clarity. Coils 44 comprise a cylindrical coil core 46 and a ferrite ring 48 and are typically 15 to 25 mm diameter. Apertures 52 in lid portion 42 are typically around 10 to 20 mm in diameter and align with channels 36 so as to provide a through channel for the electron beam. Channels 36 are interconnected by grooves 54 in base portion 40 to allow wiring to run between coils 44 and two bypass potentiometers 56. The separate lid portion simplifies insertion and wiring of coils 44 within base portion 40, and potentiometers 56 are typically digitally responsive to allow for ease of adjustment once lid 42 is secured to base 40. Lid portion 42 incorporates vent apertures to allow evacuation of the inner region of plate 32 when chamber 22 is evacuated ready for welding.

Single electromagnetic coils 44 can be used within each channel 36 as shown in FIG. 3 or multiple coils can be used as deflector elements as shown in FIGS. 4 and 5 depending on the localised adjustments required for electron beam 14 as it passes through plate 32 and thus different types of coil can be provided to allow for beam shaping and focus control.

In FIG. 4, cylindrical deflection coil 60 is used in combination with cylindrical focus coil 62 and cylindrical oscillator coil 64 with wiring 70 connecting the coils to potentiometer trimmer 72 and thence to an electrical input associated with deflection plate 32. The electromagnetic coils are secured in position by a sleeve 68 which is formed from a material transparent to electron beams, for example Perspex. Typically electromagnetic coils 44 will be connected in series in one or more groups so as to reduce the amount of wiring required.

By having beam oscillation deflector elements 64 added to each deflector element location, the main rapid deflection system incorporated in gun 12 can omit oscillation deflectors. Thus the bandwidth required of the main electron gun deflection system can be reduced allowing better positional accuracy and allowing more components to be welded over a larger area without error.

FIG. 5 shows an alternative plate design where cylindrical deflection coil 60 is combined with a cylindrical stigmator coil 80. Stigmator beam shaping improves the beam quality and ensures electron beam gun 12 does not have to dynamically change the stigmatism or focusing of the beam at the rapid rate that beam 14 is repositioning to each component location. By providing a deflector element that enables beam shaping within plate 32 instead of within electron beam gun 12, the bandwidth required of the electron gun control systems is reduced as the beam shaping systems commonly have a higher inductance than the deflection system, so are not as easily controlled at high speeds.

Apertures 34 and associated channels 36 are typically provided in an offset array as shown in FIG. 2 with five columns each having five apertures, each column being offset from the adjacent column with a regular offset such that apertures in alternate columns are horizontally aligned. It will be appreciated that the size and shape of plate 32 and the number of apertures provided will vary depending on the nature of the workpiece to be welded and the number and spacing of weld sites on workpiece 26 that need to be accommodated.

The strength and orientation of the magnetic field generated by each electromagnetic coil 44 depends on the distance of travel and inclination of electron beam 14 from the central undeflected axis to the plate apertures 34. As can be seen in FIG. 1 where three separate positions 20, 20′, 20″of electron beam 14 are shown for three separate component weld sites, the angle of incidence varies. Typically electromagnetic coils positioned in plate 32 furthest from the undeflected axis will be wound with the largest number of coils so as to generate the largest magnetic field. The remaining coils are wound to give a field in proportion to the furthest position with typically no field being required at centre point 90 which corresponds to the undeflected axis of electron beam 14 as it leaves gun 12.

By way of example, FIG. 2 shows the number of coil turns, and hence the relative magnetic field strengths, of the different electromagnetic coils positioned in each channel and their rotation relative to each other as shown by the positioning of individual numbers within the apertures relative to a normal upright reading view. Thus the magnetic field strength of each individual deflector element 44 is set so that as the distance of a welding site from the centre of the machine and the undeflected beam position increases, the magnetic field strength of the deflector element increases. Each deflector element 44 can have an adjustable fine setting control to adjust rotation and strength of its magnetic field to ensure the deflection is correct for the angle of the electron beam being deflected to it and to ensure the electron beam is directed through the tooling jig 30 at an angle that is most perpendicular to part 28. Instead of electromagnetic coils, electrostatic plates or permanent magnets can be used as deflector elements.

Fine adjustment of each deflector element's magnetic field strength and rotational alignment can be through manual, mechanical, electrical or electromechanical methods. Electrical wiring of the deflector elements 44, 60, 62, 64 can be done in series or parallel as is most suitable for the welding application and the control system can use analogue or digital control as is suitable for the welding application.

Plate 32 located in chamber 22 on top of clamping jig 30 ensures an electron beam can be widely and rapidly distributed to multiple weld sites for parts that are held in clamping tooling without any issues arising from the electron beam being impeded or distorted by that tooling. By providing a distributed array of electron beam deflector elements with at least one localised deflector element positioned above each component to be welded, the electron beam can redirected to a weld site on a component or part at an angle substantially perpendicular to the component, and so substantially orthogonal to the weld site, ensuring that impediment of the beam by the tooling jig 30 is minimised.

When setting up and testing deflection plate 32 for welding of a plurality of identical parts, for example a succession of vehicle batteries, as shown in FIG. 5 metallic plates 90 with a small aperture 92 can be inserted into the centre of channels 36 and, instead of the workpiece, a beam collector 94 placed below channels 36 where the deflector elements are located. Control software associated with gun 12 deflects electron beam 14 to each channel 36 and measures the positional accuracy of each deflector element 44 when deflecting an electron beam onto collector 94. Automated software or a manual operator can finely correct deflector element 44 within plate 32 to give optimum beam positioning on collector 94, and so ensure good quality welding. If aperture 92 is of small enough diameter, power distribution analysis can be undertaken to assist corrections by software or an operator to optimise the beam quality at each location.

To enable process monitoring when the system is being used for manufacturing, beam analysis stations 100 can be added between deflector element locations 36, see FIG. 7. Suitable beam analysis stations 100 are a piece of electrically isolated wire, or a slit or pinhole faraday cup-type beam collector 102 so that for every part that is processed the beam quality can be measured at multiple locations across the part.

Further process monitoring can be performed by an array of backscattered electron detectors placed on a roof of the processing vacuum chamber 22 to analyse electrons that are emitted and reflected to the roof of the vacuum chamber 22 during the component processing.

Further process monitoring can be performed by an array of optical cameras placed within outside of the vacuum chamber 22 viewing in through a lead glass window.

1. An electron beam deflector for use in electron beam welding, the deflector comprising a planar body defining at least one channel enabling passage of an electron beam, wherein at least one deflector element is disposed within the at least one channel and the at least one deflector element is configured to modify the direction of travel of an electron beam.

2. An electron beam deflector according to claim 1, wherein the deflector element is configured to deflect an electron beam to be incident substantially orthogonal to a weld site of a workpiece.

3. An electron beam deflector according to claim 1 configured to be locatable within a vacuum.

4. An electron beam deflector according to claim 1, further comprising a plurality of channels with at least one deflector element disposed within each channel.

5. An electron beam deflector according to claim 4, wherein each deflector element has a magnetic field strength and orientation dependent on distance from an undeflected axis of the electron beam.

6. An electron beam deflector according to claim 4, wherein the plurality of channels are arranged as an array.

7. An electron beam deflector according to claim 4, wherein the plurality of channels are arranged as an offset array.

8. An electron beam deflector according to claim 1, wherein the planar body comprises a separate base portion and a lid portion connectable together.

9. An electron beam deflector according to claim 8, wherein each channel is formed within the base portion and grooves formed within the base portion connect to each channel.

10. An electron beam deflector according to claim 8, wherein the lid portion is formed with apertures corresponding to locations of channels within the base portion.

11. An electron beam deflector according to claim 1, further comprising a plurality of deflector elements within each channel, each deflector element configured to modify a different aspect of an electron beam.

12. An electron beam deflector according to claim 1, wherein each deflector element comprises an electromagnetic coil.
